(19) United States
(12) Patent Application Publication
(10) Pub. No.: US 2021/0135056 A1
(43) Pub. Date: May 6, 2021

(54) INORGANIC-ORGANIC FILM FOR CONDUCTIVE, FLEXIBLE, AND TRANSPARENT ELECTRODES

(71) Applicant: KING ABDULLAH UNIVERSITY OF SCIENCE AND TECHNOLOGY, Thuwal (SA)

(72) Inventors: Devendra SINGH, Thuwal (SA); Gilles LUBINEAU, Thuwal (SA)

(21) Appl. No.: 17/046,564

(22) PCT Filed: Apr. 5, 2019
(86) PCT No.: PCT/IB2019/052832

§ 371 Date: Oct. 9, 2020

Related U.S. Application Data
(60) Provisional application No. 62/665,574, filed on May 2, 2018.

(51) Int. Cl. H01L 33/42; H01L 33/00; H01L 31/0224; H01L 31/18

(52) U.S. Cl. CPC H01L 33/42; H01L 33/005; H01L 31/1884; H01L 31/022425; H01L 31/022475

(57) ABSTRACT

An electrode includes a polymer based substrate; a polymer based buffer layer, wherein the polymer buffer layer includes a first polymer that is doped with a second polymer and further includes a polar solvent to increase its electrical conductivity; and a conducting film formed on the polymer based buffer layer, the conducting film being transparent to visible light. The electrode is flexible, electrically conductive and transparent to the visible light.

### CROSS-REFERENCE TO RELATED APPLICATIONS

This application claims priority to U.S. Provisional Patent Application No. 62/665,574, filed on May 2, 2018, entitled “SYNERGETIC LAYERED INORGANIC-ORGANIC FILM FOR CONDUCTIVE, FLEXIBLE AND TRANSPARENT ELECTRODES,” the disclosure of which is incorporated herein by reference in its entirety.

### BACKGROUND

### Technical Field

Embodiments of the subject matter disclosed herein generally relate to flexible, electronic and/or optic devices, and more specifically, to an electrode of such a device, that is flexible, transparent and has a low resistance.

### Discussion of the Background

Creating the next generation of transparent electrodes with mechanical flexibility and stretchability has proven to be a challenge in electronics, including optoelectronics, solar cells, touch screens and displays, and smart wearables. Among the highly conducting and transparent materials suitable for conductive and transparent electrodes for such devices, indium tin-oxide (ITO) is one of the most widely used material, specifically in the display industry and photovoltaic markets. In addition to its high transmittance in the visible region, and its low electrical resistivity, ITO possesses a good chemical stability, and can be easily fabricated using currently available techniques.

This makes the ITO a good candidate for numerous applications, including flat panel/liquid-crystal/electrochromic displays, various sensors, solar cells, thin film transistors, UV photodetectors, and laser diodes. Although natural sources of Indium are limited in nature and, one day, they will get depleted, ITO films are still the first choice for relevant industries. This is so because Indium possesses exceptional electronic properties and environmental stability. However, various alternatives are being considered, including conducting polymers, carbon allotropes or nanostructured material networks. At the moment, these materials do not outmatch the ITO films in terms of initial conductivity and environmental stability.

Currently, high quality ITO films are prepared using a great variety of deposition techniques including, but not limited to, vacuum evaporation, magnetron sputtering (DC and RF), molecular beam epitaxy, pulsed laser deposition, chemical vapor deposition, spray pyrolysis, sol-gel reaction etc. Due to its superior controllability, high uniformity over large area substrates and high deposition rate, magnetron sputtering is the most widely used technique for thin film deposition. To obtain high quality uniform ITO films, most techniques require high deposition temperatures (400° C. or higher). This high temperature makes these techniques unsuitable for the fabrication of polymer-based layers on flexible substrates, as the polymer-based layers can only be deposited at low substrate temperatures.

However, current trends in the flexible electronics field raise the issue of brittle behavior for polycrystalline ITO films and its derivatives (InZnO, InZnAlO, InGaZnO, InZnSnO etc), which is a restricting factor in their applications, in spite of their high transparency and low resistivity.

Indeed, the development of channel cracks in ITO, when stretched, has a detrimental effect on the electrical conductivity and optical transparency of the electrodes. Although this phenomenon has been known and frequently investigated, the underlying mechanisms of channel cracking have only recently been shown not to affect the conductivity of the cracked electrodes. In other words, the delamination between the ITO layer and the substrate affects the conductivity of the ITO layer rather than the cracking itself.

Thus, there is a need to manufacture electrodes for the applications noted above so that they are capable of maintaining a good conductivity and avoid or minimize delamination from their substrate.

### SUMMARY

According to an embodiment, there is an electrode that includes a polymer based substrate, a polymer based buffer layer, wherein the polymer buffer layer includes a first polymer that is doped with a second polymer and further includes a polar solvent to increase its electrical conductivity, and a conducting film formed on the polymer based buffer layer, the conducting film being transparent to visible light. The electrode is flexible, electrically conductive and transparent to the visible light.

According to another embodiment, there is a flexible device that includes a body and a flexible, conductive, and transparent electrode formed on the body. The electrode includes a polymer based substrate, a polymer based buffer layer, wherein the polymer buffer layer includes a first polymer that is doped with a second polymer and further includes a polar solvent to increase its electrical conductivity, and a conducting film formed on the polymer based buffer layer, the conducting film being transparent to visible light.

According to yet another embodiment, there is a method for making an electrode. The method includes providing a polymer based substrate, forming a polymer based buffer layer on the polymer based substrate, wherein the polymer buffer layer includes a first polymer that is doped with a second polymer and further includes a polar solvent to increase its electrical conductivity, and forming a conducting film, which is transparent to visible light, directly onto the polymer based buffer layer. The electrode is flexible, electrically conductive and transparent to the visible light.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a flowchart of a method for making a flexible, transparent, and conductive electrode;

FIGS. 2A to 2D illustrate various steps for making the flexible, transparent, and conductive electrode;

FIG. 3 illustrates a device to which flexible, transparent, and conductive electrodes are attached;

FIG. 4 illustrates a transistor having flexible, transparent, and conductive electrodes;

FIG. 5A illustrates the crystalline structure determined by analysis of the X-ray diffraction measurements for various materials, and FIG. 5B illustrates the specular optical transmittance for these materials;

FIGS. 6A-6C illustrate the sheet resistance when a strain is applied with a four-probe system to three different structures;

FIGS. 7A-7C illustrate the sheet resistance when a strain is applied with a two-probe system to the three different structures;

FIGS. 8A and 8B illustrate the change in channel cracking rate with respect to strain for various materials; and

FIG. 9 illustrates average sheet resistances with respect to strain for different relative humidity levels and ambient temperatures.

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a flexible, transparent, and conductive electrode that can be used for optoelectronics. However, those skilled in the art would understand that this electrode can be used for other devices.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a method for making ITO films with the ability to both flex and stretch (bending cycling and tensile strain) is now discussed. Such a method would have a large impact on the durability, performance and stability of transparent electrodes for the applications mentioned in the Background section.

According to this method, an organic material is used, in a synergetic way, with the ITO films, to further improve the properties of the ITO/substrate interface. For example, the present embodiment uses the polymer poly-(3,4-ethylenedioxythiophene) (PEDOT), doped with poly-(styrenesulfonic acid) (PSS), which serves as counter-ion for the positively charged PEDOT, to fabricate the ITO films on a given substrate. However, we note that PEDOT/PSS is here one application example among others and, possibly any type of conductive polymer can be used. The combination of PEDOT and PSS is called herein “PEDOT:PSS.” The PEDOT:PSS material has emerged as a good conductive polymer, due to its high conductivity and overall performance among other alternatives in aqueous form. [1], [2] Its conductive performance can be significantly improved by using solvents. Indeed, ethylene glycol or DMSO, for example, produces a rearrangement of the morphology of the films, thus promoting a phase separation between the conducting PEDOT and the insulating PSS. This leads to a better conducting network, and can even change the work function of the film. [3], [4], [5] Large increases in the PEDOT:PSS conductivity have been reported when using a polar solvent such as ethylene glycol (EG). [6]

Due to their inherent flexibility, conductive polymers are good candidates for flexible electronics. They can sustain higher strains and large numbers of bending cycles before being damaged. However, the polymers also show some important limitations. Their conductivities are usually lower than those of ITO-based solutions, and they suffer from a poor environmental stability. Due to its highly hygroscopic nature, PEDOT:PSS's behavior is temperature- and moisture-dependent, which results in degraded properties.

In one embodiment, the valuable properties of ITO (conductive, transparent, robust in harsh environment) have been merged with those of doped PEDOT:PSS (conductive, transparent, flexible). In this embodiment, a synergetic layered structure is obtained from the sputtered ITO film, together with an intermediate (or buffer) layer of EG-doped PEDOT:PSS on a Polyethylene terephthalate (PET) substrate for potential flexible optoelectronic applications. Using PET as the substrate (note that other substrates may also be used), the following structures have been generated: (1) ITO on PET (now onwards IP), (2) PEDOT:PSS on PET (now onwards PP), and (3) ITO on PEDOT:PSS on PET (now onwards IPP). Each of these structures has been tested for various parameters as discussed later.

For each one of the three structures noted above, the effects from annealing have also been quantified. The experiments performed by the inventors (their results are discussed later) demonstrate that the hybrid IPP layer, in which a very thin PEDOT:PSS buffer layer is introduced at the ITO/PET interface, possesses advantageous properties, somewhat “in-between” those of the IP and PP single-layer structures.

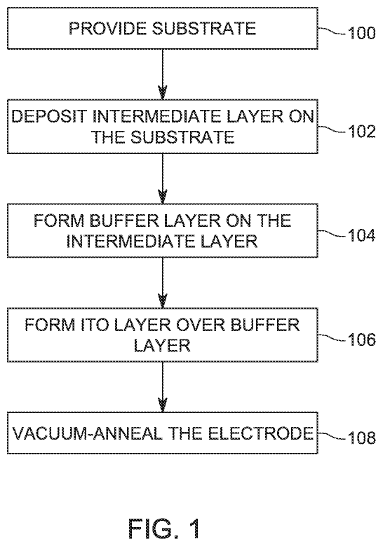

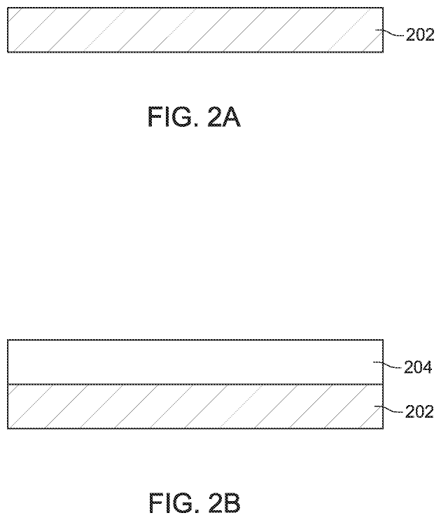

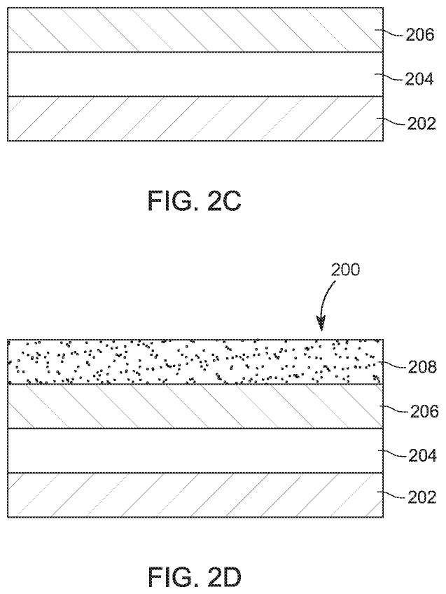

A method for making the IPP structure is now discussed with regard to FIGS. 1 and 2. FIG. 1 is a flowchart of a method for making the IPP structure. The method starts in step 100, where a substrate is provided. The substrate may include one or more of a variety of flexible materials. However, for this embodiment, PET was used. More specifically, cleaned PET sheets (250 μm thick) 202 (see FIG. 2A) are used as the base substrate to deposit the required consecutive layers. For example, PET substrates were cleaned by sonication, for 5 min each, in acetone, IPA and de-ionized water in this order. Then, the PET substrate was dried with nitrogen gas, followed by a heat treatment, at 120° C., in air. Why these details are presented to enable one skilled in the art to make the electrode 200 described herein as it was made by the inventors, those skilled in the art would understand that many variations are possible for this step.

In step 102, one or more intermediate layers 204 (e.g., between zero and ten layers, each layer having a thickness of about 5 nm) of hydrophilic 3-aminopropyltriethoxysilane (APTES) is grown on the PET substrate 202. The intermediate APTES layer(s) may be deposited on the PET substrate 202 by using a molecular vapor deposition (MVD) technique. Note that other materials may be used to form layer 204 as long as these materials bond well to the films to be deposited later and/or to the substrate 202. The adsorption of the intermediate APTES layer 204 (likely through hydrogen bonding by the amine) to the polymer substrate 202 (PET in this case) helps the formation of lateral bonds which, in turn, help the formation of a multilayer via adhesion [7], [8]. Note that forming the intermediate layer 204 is optional.

Because of its simple structure and low cost, the MVD technique has been selected to deposit the intermediate hydrophilic layer of APTES. Those skilled in the art would understand that other techniques may be used for depositing the intermediate layer 204. However, if the MVD technique is used, an O₂ plasma treatment is performed at 200 W, with an oxygen content of 200 sccm, for 100 sec (inside a MVD tool). To obtain a few intermediate layers of APTES (˜5 nm), the chamber pressure was kept at 4 mTorr and the temperature at 35° C. Again, these details of step 102 are provided for enablement and not for limiting the invention. Those skilled in the art could use other parameters and/or methods for achieving the same result.

Next, in step 104, a buffer layer 206 (e.g., PEDOT:PSS layer in this embodiment) is formed (see FIG. 2C) over the intermediate layer 204. To obtain the buffer layer 206 of highly conductive PEDOT:PSS, an aqueous dispersion of PEDOT:PSS with a 3 wt. % of an ethylene glycol (EG) polar solvent was blended at 500 RPM, for 6 hours, using magnetic stirring. [4] Note that the EG polar solvent may have any weight concentration between zero and 10%. For this step, the APTES-coated PET substrate 202 was immediately spin-coated with an as-prepared EG-doped PEDOT:PSS solution (speed of 5000 rpm, for 30 secs) to obtain the thin layer 206. In one embodiment, a thickness of the buffer layer is about 50 nm.

In step 106, the ITO thin film 208 was formed over the buffer layer 206 as shown in FIG. 2D. Note that other elements may be used for forming the thin film 208 as long as these elements have a good electrical conductivity and are transparent to visible light. For this step, one or more of the process parameters of the RF magnetron sputtering technique are optimized in order to obtain the highly conducting and transparent ITO thin film deposited (thickness ˜100 nm) on the different layered substrates, at room temperature. Depending on the sample, the optimized ITO film is deposited either directly on the PET substrate for the IP configuration, or on the buffer PEDOT:PSS layer that is beforehand deposited on the PET substrate, for the IPP configuration.

To obtain a high-quality ITO thin film 208 having a thickness of about 100 nm, the ITO material was deposited on the desired substrate at room temperature. Optimal deposition conditions were found to be at a sputtering power of 60 W, 3 mTorr sputtering pressure, 25 sccm of Argon gas flow, with a 7 cm-distance between the sample and the target, and with a substrate speed of rotation of 20 rpm. Those skilled in the art would understand that these conditions could be modified to still achieve the same results. Same of the deposited films were vacuum-annealed in step 108, at 150° C., for two hours.

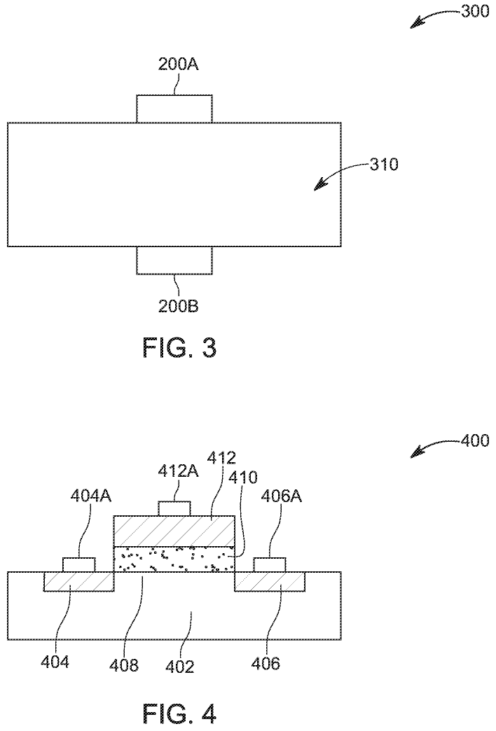

The electrode 200 having the structure shown in FIG. 2D is flexible, conductive and transparent to visible light. This electrode can be used, as shown in FIG. 3, with an electronic and/or optical device 300. Such device 300 may be any of an optoelectronics, solar cell, touch screen, display, or smart wearable device that includes at least a body 310. This device is shown in FIG. 3 having two electrodes, a first one 200A on one side of the body and a second one 200B on another side of the body. The location of the electrodes can be changed as dictated by the specific characteristics of the body and the type of device.

More specifically, as illustrated in FIG. 4, the electrode 200 discussed with regard to FIGS. 1 and 2D may be used in conjunction with a transistor 400. The transistor includes a substrate 402 in which a source 404 and a drain 406 are formed. A channel region 408 is formed between the source and drain. A gate 412 is formed over the channel region 408, with an insulator layer 410 formed between the channel and the gate. Corresponding electrodes 404A, 406A, and 412A (having a structure similar to electrode 200) are formed for each of the source, drain and gate. These electrodes may be formed with the method discussed with regard to FIG. 1. Note that for a flexibly device 300 or 400, it is desired that their electrodes are flexible, a quality provided by the electrode 200 discussed above. In one embodiment, it is desired that these devices process light. Thus, an electrode 200 which is not only flexible, but also transparent to light is necessary for these devices. In another embodiment, the electrode needs to be a good conductor. As will be seen in the next paragraphs, the electrode 200 is a very good conductor. Other devices than 300 and 400 may benefit such electrodes.

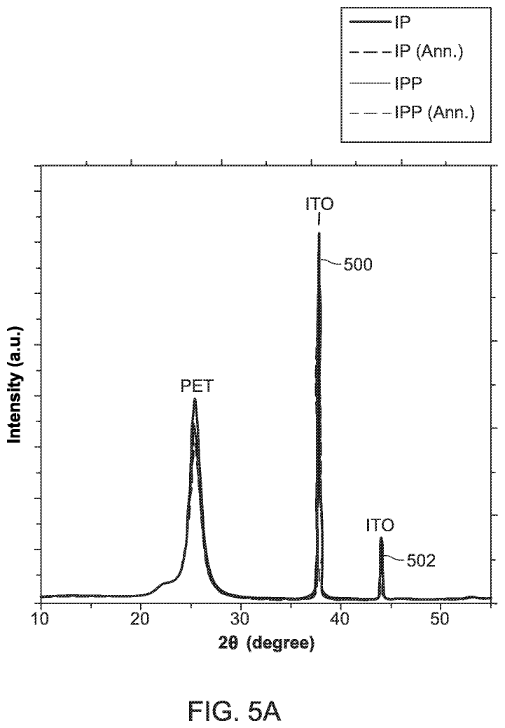

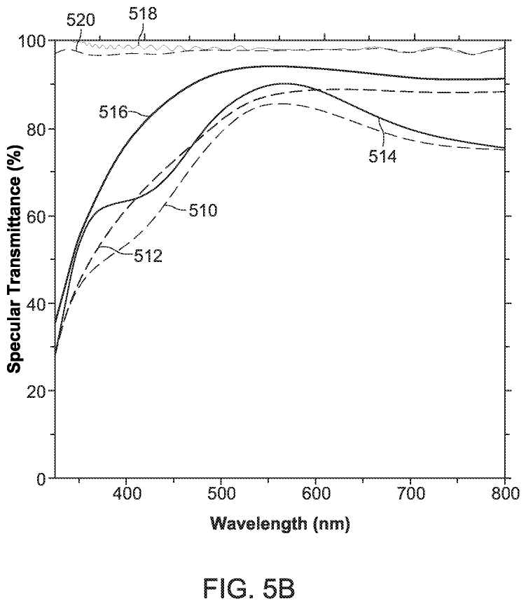

Various tests have been performed on the IP, PP and IPP structures discussed above. One of these tests determined the crystalline structure of the electrode. The crystalline structure (i.e., size and orientation of the grains) was determined by analysis of the X-ray diffraction (XRD) measurements, for the 2θ range of 10-55° (see FIG. 5A). The XRD patterns obtained for the as-prepared film (with no annealing) confirm the uniform growth of the ITO-deposited layer. Grain sizes for ITO films deposited on different substrates were estimated using the Scherrer formula (d=0.9λ/β cos θ), where d is the crystallite size, λ the wavelength of the X-rays, β the full width at half-maximum, and θ is the Bragg angle. The estimated crystallite size, calculated with preferred (411) orientation, was found to be ˜48±2 nm. Typical XRD patterns of sputtered ITO thin films in IP- and IPP-layered structures showed a reflection with sharp peaks 500 and 502 at ˜37.65° and ˜45°, which correspond to the preferred orientations of (411) and (431) planes of ITO, respectively.

The specular optical transmittance for the various sets of samples in the wavelength range of 300-800 nm is shown in FIG. 5B. Curve 510 corresponds to IPP annealed, curve 512 corresponds to IP annealed, curve 514 corresponds to IPP, curve 516 corresponds to IP, curve 518 corresponds to PP and curve 520 corresponds to PP annealed. The PP sheet curve is almost identical to curve 510. The results show that the average transmittance values are, as-expected, dependent on the number of layers and materials involved. The transparency 516 of the hybrid IPP structure is very competitive in the wavelength range of 300-600 nm. Its transparency decreases by 10%, when compared to ITO at higher wavelengths (600 nm to 800 nm), but is still reasonable for most applications. The haze value for the prepared samples is not shown, as it is consistently less than 2% for all samples. Low haze is requested for applications that require high transparency and clarity (e.g., flexible displays and touch screens). The used samples, which feature both low haze (less than 2%) and high transparency (more than 85% measured at a wavelength of 550 nm), are thus good candidates for such applications.

Microscopic studies were also carried out to observe the surface morphology of the sputter-deposited ITO films on a typical PP structure. Scanning Electron Microscope (SEM) images of a typical sample of sputtered ITO thin film deposited on PEDOT:PSS on PET substrate has been taken at room temperature, and these images show a uniform distribution of grains, with an estimated size of 50 nm, comparable to the pattern obtained by XRD diffraction.

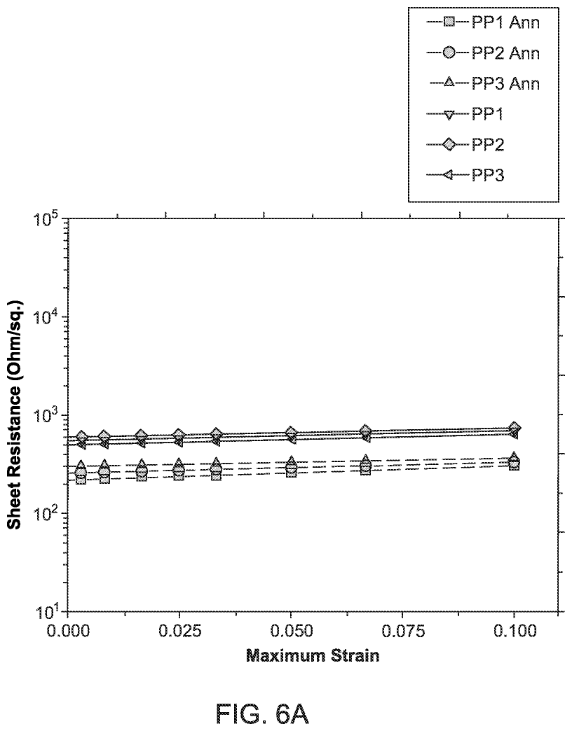

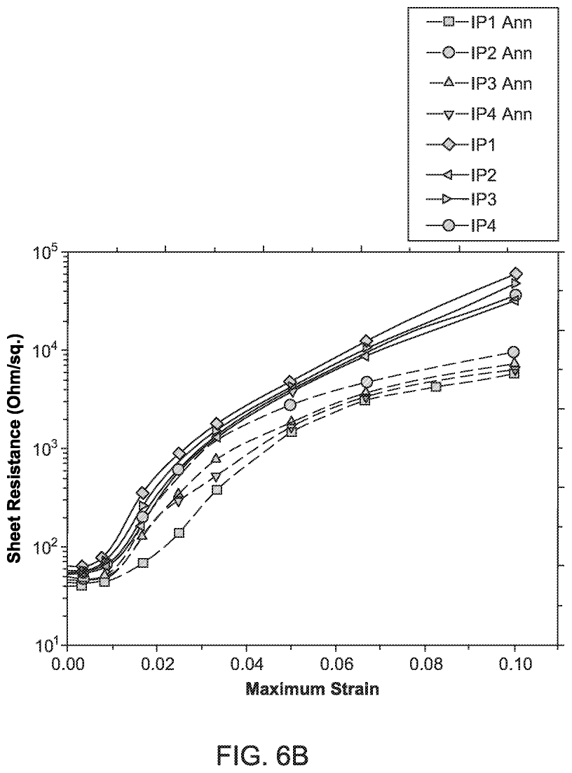

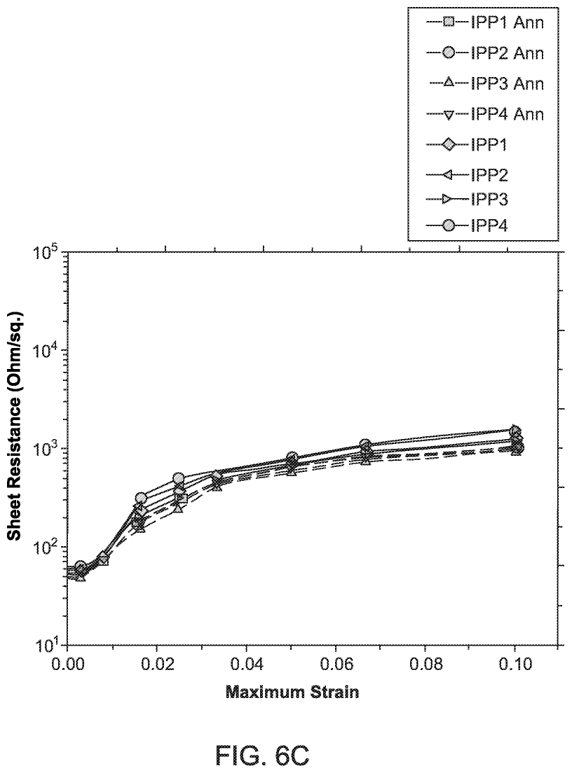

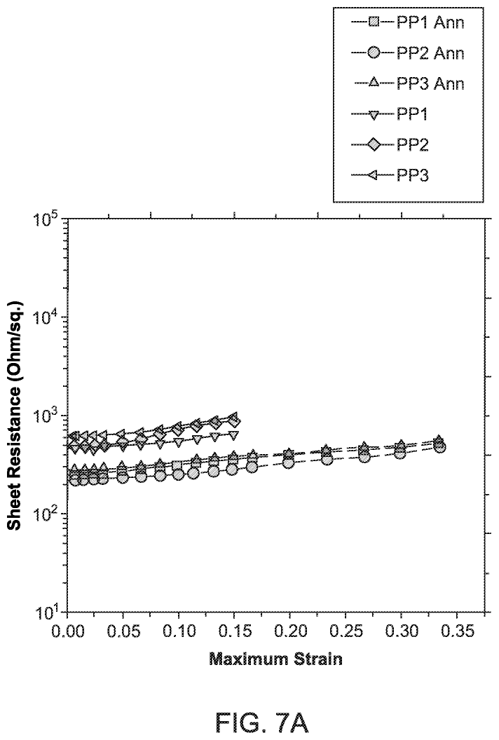

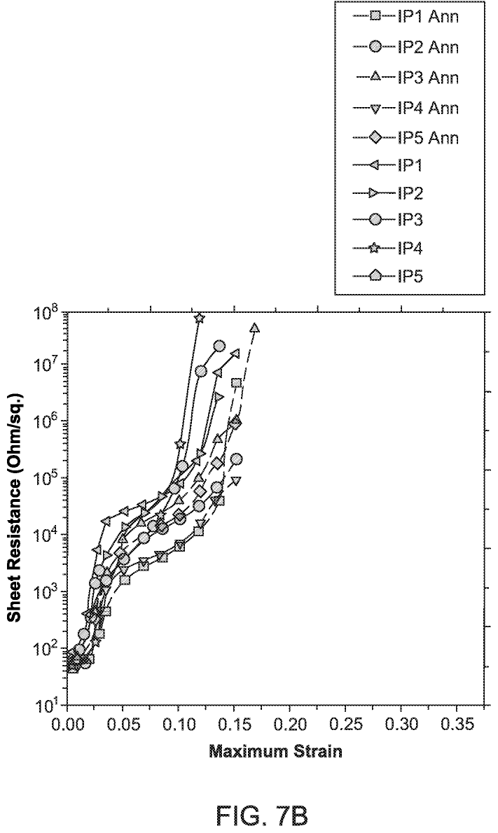

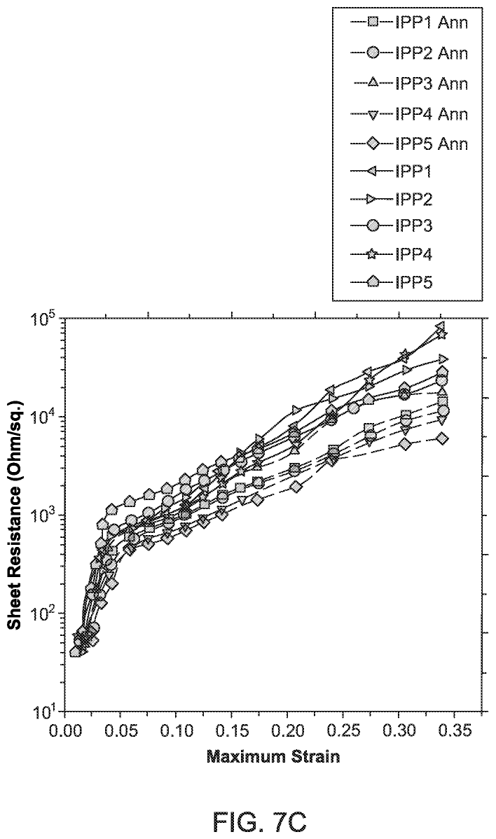

The electro-mechanical response of the strained thin films of the electrode 200 has also been investigated. In this study, the change in electrical resistance of the film when discrete degradations such as channel cracks and associated delamination are introduced were also studied. The experiment involved stretching the films in a tension mode to introduce a quasi-periodical pattern of cracks, and subsequently monitoring the change in electrical resistance as a function of the maximum applied strain, as well as a function of the crack density. The electrical resistance was first measured either after unloading the film (with a four-probe, as illustrated in FIGS. 6A to 6C), or on the loaded film, using an in-situ two-probe technique as illustrated in FIGS. 7A to 7C. Then, the electrical resistance was correlated with the crack density. All in-situ microscopic images of the various specimens were captured under controlled applied micro-tensile strain. In-situ SEM images were then acquired during the micro-tensile testing of typical IPP stacked structure (annealed).

For the micro-tensile testing, the following conditions were observed. Straight rectangular samples (80 mm×10 mm) were obtained from films coated on 5″ PET substrates. The 4-point probe measurements were performed using Advanced Instrument technology (CMT Series), with a probe spacing of 1 mm. For 2-point probe measurements, linear electrodes (copper wires attached with Silver Paste) were placed on the coated side of the thin film samples. Electrodes were connected to an U2741A digital multimeter (Agilent Technologies) to measure changes in the electrical resistance, over a 30 mm gauge length, using a two-probe (in-situ) technique. All tests were performed in a controlled environment, with the temperature kept at 25° C. and relative humidity (RH) at 65% RH. The monotonic tensile tests were performed while monitoring the applied load (macroscopic strain) with a displacement rate of 1 mm/min, the crack density, as well as changes in the electrical resistance of the samples.

The tests were divided into multiple incremental loading/unloading cycles in order to have a maximum extension of 10%. After reaching a maximum extension for each cycle, the samples were partially unloaded to measure their post-cycling electrical resistance. All sets of thin film samples were tested to confirm the reproducibility of the experiments. Optical images were obtained for a region of interest located at the center of the specimen, using a microscope. Digital images were used to track the number of cracks during tests, and to evaluate the applied macroscopic strain. All in-situ microscopic images of various specimens were captured under controlled applied micro-tensile strain, using a specialized 1 kN Tensile Module.

FIGS. 6A to 6C illustrate the applied strain versus the residual sheet resistance (after each loading/unloading cycle), for the following sets of deposited films: (a) PP as shown in FIG. 6A, (b) IP as shown in FIG. 6B, and (c) IPP as shown in FIG. 6C. Both annealed and not annealed samples were considered. It was found that, for as-deposited PP layers (whose conductivity only relied on PEDOT/PSS), the initial sheet resistance (four-probe, see FIG. 6A) was significantly higher (˜500-700 Ohm/sq) than that of layered structures containing ITO (IP or IPP, see FIGS. 6B and 6C). Note that an “as-deposited” layer is understood here to be a layer made without the final step 108 of annealing illustrated in FIG. 1. An “as-deposited and annealed layer” is understood to be made to include the annealing step 108. Further, vacuum annealing of the samples, at 150° C., for 2 hours, showed a slight improvement in the electrical sheet resistance (˜200-400 Ohm/sq). For as-deposited and annealed IP layers, the initial sheet resistance was significantly lower (˜50-60 Ohm/sq), but it drastically increased (up to 10⁴ to 10⁵ ohm/sq with a 5-10% strain) as soon as the macroscopic strain resulted in the degradation of the structure.

These results are explained as follows. At low strains, channel cracks run perpendicular to the loading direction and tend to form a quasi-periodical network with the increasing crack density. At higher strains, Poisson's effect induces transverse contraction, resulting in localized buckling and delamination. Previous studies have shown that the presence of delamination at a very early stage in the loading (due to a concentration of the stress at the crack tips) is the main responsible for the degradation of electrical performance. On the other hand, a hybrid performance was observed for as-deposited and annealed IPP layers (see FIG. 6C). The initial sheet resistance (˜50-60 Ohm/sq) competed with ITO, and appeared to gain in stability from the presence of PEDOT:PSS, as it increased only up to 10³ ohm/sq at high strains (5-10% strain). The layered IPP structures showed a clear synergetic effect in improving the overall performance.

For the monotonic tensile loading, the in-situ electrical resistance was measured with respect to the applied strain and the results are shown in FIGS. 7A to 7C for various sets of deposited films as follows: (a) PP shown in FIG. 7A, (b) IP shown in FIG. 7B, and (c) IPP shown in FIG. 7C, all of these with various sets of as-deposited and annealed samples. Similar conclusions can be drawn for all in-situ measurements. However, due to the wider opening of the cracks in the loaded sample, the resistance measured in-situ is always higher than for unloaded samples shown in FIGS. 6A to 6C. As-deposited and annealed IP layered structures displayed a significant rise in sheet resistance (up to 10⁸ ohm/sq with 10-15% strain). However, for as-deposited and annealed IPP layered structures, it was found that sheet resistance gradually increases (up to 10³ and then to 10⁴ ohm/sq with 15% and then 30% strain). The ability of the intermediate conductive layer to improve the stability of the film's conductivity when cracking appears is visible here.

From these tests, it was observed that the sheet resistance values for PEDOT-based films are higher than those for an ITO-based layered structure. When strain is applied, the sheet resistance for PEDOT-based films only shows nominal changes, whereas the sheet resistance for ITO films displays an increase by eight orders of magnitude, as soon as strain is applied. Thus, combining ITO with PEDOT in a composite layered structure results in a hybrid behavior characterized by high initial conductivity and high stability.

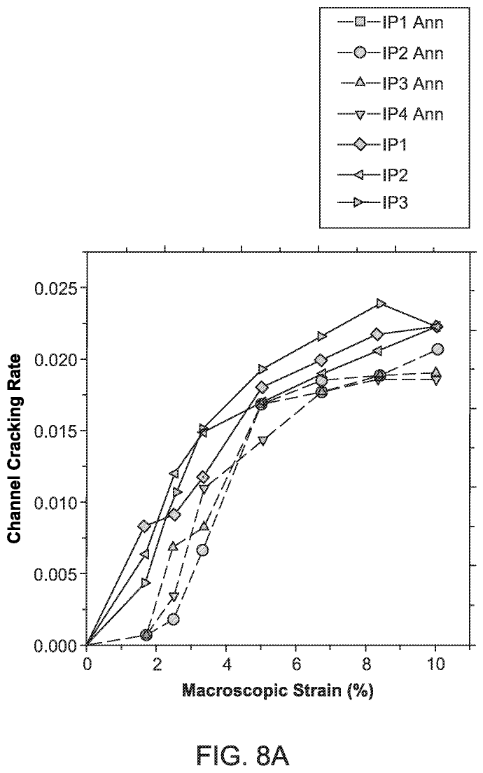

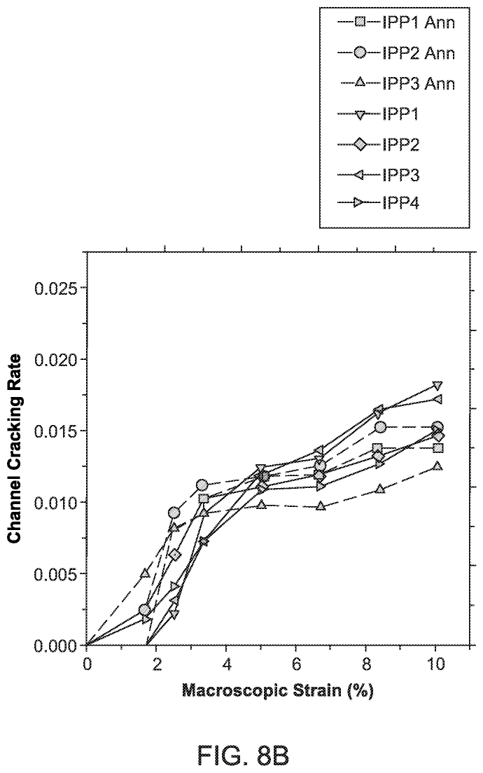

Next, the effect of channel crack density is discussed with regard to the novel IPP structure. The change in the electrical resistance in traditional layered structures is associated mainly with the multiplication of transverse cracks that trigger delamination between the conductive ITO and the substrate. For this reason, the dynamics of the multiplication of cracks in the IPP layered structure was investigated. For this investigation, in-situ SEM images were acquired during micro-tensile testing of an IPP stacked structure. Average strain values applied to the studied IPP structure were 1.67%, 3.33%, 6.67%, and 10%. The advantage of SEM images is that they offer very good contrast, which makes it possible to easily observe the characteristic features of the cracked pattern. The obtained images shown the multiplication of well-percolated channel cracks that give birth to secondary cracks, when the strain is significant. The multiplication of cracks, in-situ, was observed during the monotonic tensile tests presented above using optical microscopy. The corresponding digital images were used to both track the number of cracks during the test and evaluate the applied strain over the region of interest. To quantify the crack spacing with respect to the coating thickness, a dimensionless channel cracking rate ρ was defined, where ρ=h_{c}/L, with h_{c} being the coating layer thickness and L being the average inter-crack spacing, which is equal to the length of the region of interest (ROI) over which the cracks are counted and then divided by the number of cracks. FIGS. 8A and 8B show the change in channel cracking rate versus the average strain, for various sets of films including (a) IP layers and (b) IPP layers, respectively, for various sets of as-deposited and annealed samples. It was found that the effect of annealing on the channel-cracking rate was very limited, whether as-deposited or annealed samples were used. However, the channel-cracking rate of IP-layered structures was found to be 25% higher than that of the IPP-layered structures. This indicates that the intermediate PEDOT/PSS layer has an additional beneficial effect on the performance of the electrode.

In summary, the first beneficial effect of the intermediate PEDOT/PSS layer is a reduction of the sensitivity of the electrical resistivity to the cracks as discussed with reference to FIGS. 6A to 7C. The second beneficial effect is that, by introducing a soft interfacial layer, it reduces the multiplication of cracks when a mechanical loading is applied. This can be attributed to the modification of the shear stress transfer at the interface.

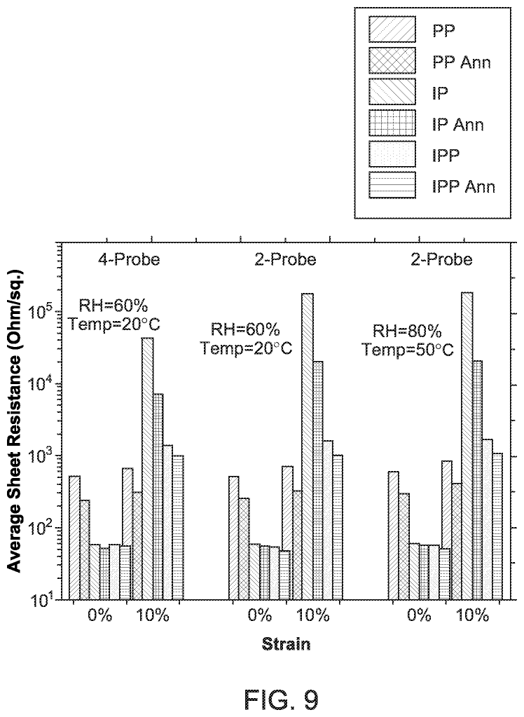

Next, environmental stability studies have been performed for the new IPP structure described with regard to FIGS. 1 to 2D. After showing that ITO and PEDOT:PSS layers have totally different responses to the environment (ITO being very stable, whereas the PEDOT:PSS's response vary), it was found that the hybrid IPP-layered structure 200 also features beneficial properties with respect to its environmental stability. Various sets of samples were studied to understand the effects of relative humidity (RH) and temperature on the electrical sheet resistance. Various IPP layered samples were placed inside a humidity and temperature control chamber controlled at 80% and 50° C. respectively, with an exposure time of one hour. The electrical sheet resistance was measured before and after exposure, under the set harsh conditions mentioned above. FIG. 9 shows the variations of the average sheet resistance (measured in four as well as in-situ two probe configurations), with the applied strain, for various sets of samples, at different relative humidities and ambient temperatures. EG-doped PEDOT:PSS based layers (as-deposited and annealed PP layers) displayed sheet resistance values up to 20% higher, compared to their initial values. ITO based films (with and without PEDOT:PSS stacks, as-deposited and annealed IP and IPP layers), showed only a negligible increase in sheet resistance (up to 2%). For structures exposed to a maximum tensile strain of 10%, it was observed that the electrical sheet resistances increased dramatically for PP structures (up to 20%), but those of IP- and IPP-layered structures did not significantly changed (less than 5%), whether the samples were as-deposited or as-annealed. From these observations, it was concluded that the novel IPP structure 200 is a layered synergetic structure having a sheet resistance with a much better stability when humidity and temperature vary.

The above discussed embodiments disclose a new design based on a conductive polymer-assisted transparent and conducting ITO layer on a flexible substrate. Highly conductive and transparent sputtered ITO films on flexible PET substrates were prepared, either with or without an intermediate layer of PEDOT:PSS. They were then compared, in terms of their potentials for stretchable electrode-based applications and it was found that the brittle intrinsic nature of ITO layers makes them unsuitable for their use in flexible and stretchable devices. However, the as-deposited PEDOT:PSS layers are prone to the environmental degradation in atmosphere. The novel electrode 200 counterbalances the limitations of both materials as the tests show that, for a range of macroscopic strain values up to 30%, the hybrid structure features a low initial resistivity and a high stability, when subjected to mechanical strains. This can be attributed to an improvement of the electrical transfer at the delaminated interfaces, due to the presence of the conductive PEDOT/PSS layer. This PEDOT/PSS layer also has a beneficial effect on the degradation kinetics, as the channel cracking density tends to be lower in the hybrid structure, compared to the ITO-only structure. An explanation for this is the change in mechanical load transfer at the interface, due to the presence of this soft layer. It was also shown that, when different sets of samples (PP, IP and IPP layers, with and without maximum strain, and for both as-deposited and annealed samples) are exposed to a harsh environment (80% relative humidity, 50° C. temperature), the electrical sheet resistance dramatically increases for PP structures, whereas that of IP and IPP layered structures does not change significantly. The results presented herein show that an integration of the highly conductive ITO layers and the supporting conducting polymer layers of PEDOT:PSS films can be used as transparent electrodes in advanced stretchable and flexible devices.

The disclosed embodiments provide an electrode that is flexible, has high conductivity, and is transparent. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

[1] M. Vosgueritchian, D. J. Lipomi, Z. Bao, Adv. Funct. Mater. 2012, 22, 421.
[2] Y. Leterrier, L. Medico, F. Demarco, J. Manson, U. Betz, M. Escola, M. K. Olsson, F. Atamny, Thin Solid Films, 2004, 460, 156.
[3] K. Sun, S. Zhang, P. Li, Y. Xia, X. Zhang, D. Du, F. H. Isikgor, J. Ouyang, J Mater Sci: Mater Electron 2015, 26, 4438.
[4] F. Greco, A. Zucca, S. Taccola, A. Menciassi, T. Fujie, H. Haniuda, S. Takeoka, P, Dario, V. Mattoli, Soft Matter, 2011, 7, 10642.
[5] D. J. Lipomi, J. A. Lee, M. Vosgueritchian, B. C. K. Tee, J. A. Bolander, Z. Bao, Chem. Mater. 2012, 24, 373.
[6] J. Zhou, D. H. Anjum, L. Chen, X. Xu, I. A. Ventura, L. Jiang, G. Lubineau, J. Mater. Chem. C, 2014, 2, 9903.
[7] V. V. Tsukruk, V. N. Bliznyuk, Langmuir 1998, 14, 446.
[8] J. A. Howarter, J. P. Youngblood, Langmuir 2006, 22, 11142.

1. An electrode comprising:
a polymer based substrate;
a polymer based buffer layer, wherein the polymer buffer layer includes a first polymer that is doped with a second polymer and further includes a polar solvent to increase its electrical conductivity; and
a conducting film formed on the polymer based buffer layer, the conducting film being transparent to visible light,
wherein the electrode is flexible, electrically conductive and transparent to the visible light.

2. The electrode of claim 1, wherein the polymer based substrate is made of polyethylene terephthalate (PET).

3. The electrode of claim 2, wherein the first polymer of the buffer layer is polymer poly-(3,4-ethylenedioxythiophene) (PEDOT).

4. The electrode of claim 3, wherein the second polymer of the buffer layer is poly-(styrenesulfonic acid) (PSS).

5. The electrode of claim 4, wherein the polar solvent is ethylene glycol (EG).

6. The electrode of claim 5, wherein the conducting film includes indium tin-oxide.

7. The electrode of claim 6, further comprising:
an intermediate layer formed between the substrate and the buffer layer.

8. The electrode of claim 7, wherein the intermediate layer includes hydrophilic 3-aminopropyltriethoxysilane (APTES).

9. A flexible device comprising:
a body; and
a flexible, conductive, and transparent electrode formed on the body,
wherein the electrode includes,
a polymer based substrate,
a polymer based buffer layer, wherein the polymer buffer layer includes a first polymer that is doped with a second polymer and further includes a polar solvent to increase its electrical conductivity, and
a conducting film formed on the polymer based buffer layer, the conducting film being transparent to visible light.

10. The flexible device of claim 9, wherein the polymer based substrate is made of polyethylene terephthalate (PET).

11. The flexible device of claim 10, wherein the first polymer of the buffer layer is polymer poly-(3,4-ethylenedioxythiophene) (PEDOT), the second polymer of the buffer layer is poly-(styrenesulfonic acid) (PSS), the polar solvent is ethylene glycol (EG), and the conducting film includes indium tin-oxide.

12. The flexible device of claim 11, further comprising:
an intermediate layer formed between the substrate and the buffer layer.

13. The flexible device of claim 12, wherein the intermediate layer includes hydrophilic 3-aminopropyltriethoxysilane (APTES).

14. The flexible device of claim 9, wherein the body is an optoelectronics device, a solar cell, a touch screen, a display, or a smart wearable device.

15. A method for making an electrode, the method comprising:
providing a polymer based substrate;
forming a polymer based buffer layer on the polymer based substrate, wherein the polymer buffer layer includes a first polymer that is doped with a second polymer and further includes a polar solvent to increase its electrical conductivity; and
forming a conducting film, which is transparent to visible light, directly onto the polymer based buffer layer,
wherein the electrode is flexible, electrically conductive and transparent to the visible light.

16. The method of claim 15, further comprising:
forming an intermediate layer directly between the substrate and the buffer layer.

17. The method of claim 16, wherein the polymer based substrate is made of polyethylene terephthalate (PET), the first polymer of the buffer layer is polymer poly-(3,4-ethylenedioxythiophene) (PEDOT), the second polymer of the buffer layer is poly-(styrenesulfonic acid) (PSS), the polar solvent is ethylene glycol (EG), the conducting film includes indium tin-oxide, and the intermediate layer includes hydrophilic 3-aminopropyltriethoxysilane (APTES).

18. The method of claim 16, wherein the intermediate layer was made by molecular vapor deposition, the polymer based buffer layer was made by spin coating, and the conducting film was formed by sputtered deposition.

19. The method of claim 18, further comprising:
vacuum annealing the electrode.

20. The method of claim 15, wherein the electrode is formed on an optoelectronics device, a solar cell, a touch screen, a display, or a smart wearable device.
